(19) United States
(12) Patent Application Publication
(10) Pub. No.: US 2026/0282575 A1
(43) Pub. Date: Sep. 17, 2026

(54) SOLID-STATE IMAGING ELEMENT AND METHOD OF MANUFACTURING THE SAME

(71) Applicant: TOPPAN HOLDINGS INC., Tokyo (JP)

(72) Inventors: Ryoma MOTEGI, Taito-ku (JP); Jin KITAZAKI, Taito-ku (JP)

(73) Assignee: TOPPAN HOLDINGS INC., Tokyo (JP)

(21) Appl. No.: 19/673,226

(22) Filed: May 11, 2026

Related U.S. Application Data
(63) Continuation of application No. PCT/JP2024/038315, filed on Oct. 28, 2024.

(30) Foreign Application Priority Data
Nov. 15, 2023 (JP) 2023-194069

(51) Int. Cl. H10F 39/00; G02B 5/18; H10F 39/18

(52) U.S. Cl. CPC H10F 39/805; G02B 5/1857; H10F 39/024; H10F 39/182; H10F 39/8063

(57) ABSTRACT

Disclosed is a solid-state imaging element in which a diffraction grating pattern is formed with high shape accuracy on a lens array and a method of manufacturing the solid-state imaging element. The solid-state imaging element o includes a lens array, a planarization layer, and a diffraction grating section. The lens array includes a plurality of microlenses arranged in a regular manner. The planarization layer is formed on the lens array. The diffraction grating section includes a thermosetting resin. The diffraction grating section includes a plurality of diffraction gratings and is provided on the planarization layer. An angle between a lower surface and a side surface of each diffraction grating is 80° or more and 100° or less.

### CROSS-REFERENCE TO RELATED APPLICATIONS

The present application is a continuation of and claims the benefit of priority to International Application No. PCT/JP 2024/038315, filed Oct. 28, 2024, which is based upon and claims the benefit of priority to Japanese Application No. 2023-194069, filed Nov. 15, 2023. The entire contents of these applications are incorporated herein by reference.

### BACKGROUND OF THE INVENTION

### Technical Field

The present disclosure relates to a solid-state imaging element. The present disclosure also refers to a method of manufacturing the solid-state imaging element.

### Description of Background Art

Development of range image sensors that capture an image including distance information to an object is underway both domestically and internationally.

In recent years, range image sensors are used in facial recognition systems on, for example, smartphones, and there is a demand for low cost and compactness. To meet this demand, three-dimensional sensing devices that use conventional CMOS image sensors have been developed.

A publication discloses an invention related to a light-field imaging device for acquiring depth and capturing three-dimensional images.

See, for example, JP 7120929 B. The entire contents of this publication are incorporated herein by reference.

### SUMMARY

A diffraction grating pattern is generally formed into a permanent film through a process of applying a photosensitive resin layer (resist), which is subjected to exposure and development, followed by heating (baking) at a high temperature.

However, it was found that the accuracy in the shape of diffraction gratings is insufficient in such pattern formation, leading to degradation of the optical characteristics.

JP 7120929 B does not disclose the detailed configuration of the diffraction gratings or the method of manufacturing the diffraction gratings.

It is an object of the present disclosure to provide a solid-state imaging element in which a diffraction grating pattern is formed with high shape accuracy on a lens array and a method of manufacturing the solid-state imaging element.

A solid-state imaging element according to one aspect of the present disclosure includes:
a lens array including a plurality of microlenses arranged in a regular manner;
a planarization layer formed on the lens array; and
a diffraction grating section including a thermosetting resin, the diffraction grating section including a plurality of diffraction gratings and being provided on the planarization layer, in which
an angle between a lower surface and a side surface of each diffraction grating is 80° or more and 110° or less.

A solid-state imaging element according to one aspect of the present disclosure includes:
a lens array including a plurality of microlenses arranged in a regular manner;
a planarization layer formed on the lens array; and
a diffraction grating section including a thermosetting resin, the diffraction grating section including a base covering an upper surface of the planarization layer and a plurality of diffraction gratings protruding from the base, in which
the base between the diffraction gratings has a surface roughness Ra of 100 Å or less.

A method of manufacturing a solid-state imaging element according to one aspect of the present disclosure includes the steps of:
(A) forming a planarization layer on a lens array including a plurality of microlenses arranged in a regular manner and forming a thermosetting resin layer on the planarization layer;
(B) forming a sacrificial pattern on the thermosetting resin layer, the sacrificial pattern corresponding to a diffraction grating;
(C) forming a plurality of diffraction gratings by performing dry etching and transferring a shape of the sacrificial pattern on the thermosetting resin layer, in which
in the step (C), an angle between a lower surface and a side surface of each diffraction grating is adjusted to be 80° or more and 110° or less.

A method of manufacturing a solid-state imaging element according to one aspect of the present disclosure includes the steps of:
(A) forming a planarization layer on a lens array including a plurality of microlenses arranged in a regular manner and forming a thermosetting resin layer on the planarization layer;
(B) forming a sacrificial pattern on the thermosetting resin layer, the sacrificial pattern corresponding to a diffraction grating; and
(C) forming a plurality of diffraction gratings by performing dry etching and transferring a shape of the sacrificial pattern on the thermosetting resin layer, in which
in the step (C), leaving part of the thermosetting resin layer between the diffraction gratings, the part of the thermosetting resin layer having a surface roughness Ra of 100 Å or less.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic cross-sectional view of a solid-state imaging element according to a present embodiment;

FIG. 2 is a schematic cross-sectional view illustrating a manufacturing process of a solid-state imaging element according to a comparative example;

FIG. 3 is a schematic view of diffraction gratings illustrating a pattern shape and diffracted light;

FIG. 4 is a schematic cross-sectional view of diffraction gratings according to one or more embodiments of the present disclosure illustrating a cross-sectional shape;

FIG. 5 is a schematic cross-sectional view of diffraction gratings according to another embodiment of the present disclosure illustrating a cross-sectional shape;

FIG. 6 is a schematic plan view of the diffraction gratings according to the present embodiment illustrating a planar shape;

FIG. 7 is a schematic cross-sectional view illustrating a manufacturing process of the solid-state imaging element according to the present embodiment;

FIG. 8 is a schematic cross-sectional view illustrating the manufacturing process of the solid-state imaging element according to the present embodiment;

FIG. 9 is a schematic cross-sectional view illustrating the manufacturing process of the solid-state imaging element according to the present embodiment;

FIG. 10 is a schematic view of scanning electron micrographs of a diffraction grating section according to the present example;

FIG. 11 describes schematic renderings of FIG. 10;

FIG. 12 is a cross-sectional profile of the diffraction gratings according to the present example;

FIG. 13 is a cross-sectional profile of the diffraction gratings according to the comparative example;

FIGS. 14A and 14B are image data used in measuring a surface roughness Ra of the surface of the diffraction grating section between the diffraction gratings; and

FIGS. 15A and 15B describe schematic renderings of FIGS. 14A and 14B, respectively.

### DETAILED DESCRIPTION OF THE EMBODIMENTS

Embodiments will now be described with reference to the accompanying drawings, wherein like reference numerals designate corresponding or identical elements throughout the various drawings.

One or more embodiments of the present disclosure (herein, collectively referred to as the “present embodiment”) will be described in detail below. Note that the present disclosure is not limited to the following embodiments and may be modified in various forms within the scope of the present disclosure. The numerical ranges expressed with “to” include numerical values (boundary values) of both a lower limit value and an upper limit value. Additionally, expressions including “upper surface,” “above/upward,” “lower surface,” and “below/downward” used in the description are defined as follows. That is, the direction in which functional layers are stacked on the surface of a substrate 20 is referred to as “above/upward,” and the direction opposite to “above/upward” is referred to as “below/downward.” Additionally, in each layer, the surface oriented in the stacking direction is referred to as the “upper surface,” and the surface on the opposite side is referred to as the “lower surface.” In other words, a light-receiving surface is referred to as the “upper surface,” and the surface on the opposite side is referred to as the “lower surface.”

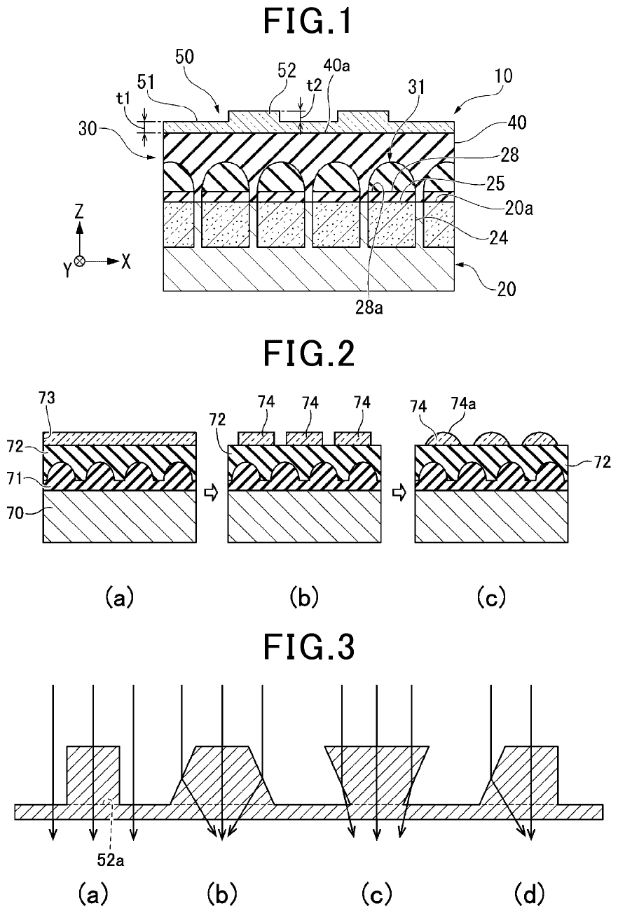

FIG. 1 is a schematic cross-sectional view of a solid-state imaging element according to the present embodiment. A solid-state imaging element 10 includes a substrate 20, a CMOS image sensor 24, a color filter 28, a lens array 30, a planarization layer 40, and a diffraction grating section 50. The solid-state imaging element 10 functions as a range image sensor as a whole.

The substrate 20 is, for example, a silicon (Si) substrate. The material of the substrate 20 may be, for example, Si, but is not limited to any particular material as long as it is possible for the material to include pixels and light-receiving elements such as the CMOS image sensor 24 and allow them to function electrically. Hereinafter, the thickness direction of the substrate 20 is referred to as a Z-direction, and the direction from the inside of the substrate 20 toward a surface 20a in the Z-direction is referred to as upward. Additionally, the direction parallel to the surface 20a and orthogonal to the Z-direction is referred to as an X-direction. The direction parallel to the surface 20a and orthogonal to the X-direction and the Z-direction is referred to as a Y-direction.

The solid-state imaging element 10 includes a plurality of CMOS image sensors 24. The plurality of CMOS image sensors 24 are arranged along each of the X-direction and the Y-direction. By providing the plurality of CMOS image sensors 24 as described above, a pixel array of the solid-state imaging element 10 is configured in the direction along the surface 20a of the substrate 20. The number of the CMOS image sensors 24 provided in the solid-state imaging element 10 is set as appropriate in accordance with, for example, the use of the solid-state imaging element 10. At least some of the CMOS image sensors 24 are illustrated in FIG. 1 and other figures.

Each of the CMOS image sensors 24 is embedded in the substrate 20 on the side of the surface 20a in the Z-direction. A light-receiving surface 25 of each CMOS image sensor 24 is exposed from the substrate 20 and is substantially flush with the surface 20a. Although the illustration of the detailed configuration of the CMOS image sensors 24 is omitted in FIG. 1 and other figures, the detailed configuration is similar to that of known CMOS image sensors.

The color filter 28 is provided on (that is, upward in the Z-direction) the light-receiving surface 25 of each of the CMOS image sensors 24. The color filter 28 functions to allow light having a wavelength band of any of the colors including red (R), green (G), and blue (B), which are three primary colors of light, to be transmitted therethrough. The color to be transmitted through the color filter 28 is determined as appropriate for each of the plurality of CMOS image sensors 24 in accordance with, for example, the position of the plurality of CMOS image sensors 24.

The lens array 30 is formed on the color filters 28 and includes a plurality of microlenses 31 arranged in a regular manner corresponding to the color filters.

The microlenses 31 are provided on surfaces 28a of the color filters 28 on the respective CMOS image sensors 24. The microlenses 31 are what is called plano-convex lenses each including a bottom and a lens face. The material of the microlenses 31 has a refractive index higher than at least the refractive index of air and the planarization layer 40. In particular, the material of the microlenses 31 is preferably a high-refractive-index material having a refractive index of, for example, approximately 1.6 to improve the focusing effect of the microlenses due to the difference between the refractive index of the microlenses 31 and the refractive index of the planarization layer 40. The curvature and the shape of the lens face is designed as appropriate in accordance with, for example, the refractive index of the material of the microlenses 31 for the visible wavelength. Further, the microlenses 31 are formed and arranged to allow light incident on the microlenses 31 from above in the Z-direction and directed opposite to the Z-direction to converge into the CMOS image sensors 24 through the color filters 28 provided below (that is, downward in the Z-direction) the microlenses 31.

The planarization layer 40 is provided to cover the surface of the lens array 30 to smooth out irregularities caused by the microlenses 31 and to form a substantially flat surface 40a for providing the diffraction grating section 50. The surface 40a of the planarization layer 40 is planarized relative to the surface of the microlenses 31. The maximum thickness of the planarization layer 40 is determined as appropriate in accordance with, for example, the optical path length required for the light incident on the microlenses 31 from above in the Z-direction. The maximum thickness of the planarization layer 40 corresponds to the distance between the surface 40a of the planarization layer 40 and the surface 20a of the substrate 20 (the surfaces of the CMOS image sensors 24) in the Z-direction.

The planarization layer 40 has a refractive index lower than at least the refractive index of the microlenses 31. As the refractive index of the planarization layer 40 approaches the refractive index of air, the difference between the refractive index of the planarization layer 40 and that of the microlenses 31 is increased. As a result, refraction of light incident on the diffraction gratings of the diffraction grating section 50 from above toward below in the Z-direction is reduced, and the path of the light incident on the diffraction gratings is directed toward a predetermined direction. This allows the light to favorably converge to the CMOS image sensors 24 by the microlenses 31, thus achieving desired optical characteristics of the solid-state imaging element 10. The refractive index of the planarization layer 40 is adjustable as appropriate.

The planarization layer 40 contains a hollow filler and a medium in one example. The hollow filler and the medium have transparency to visible wavelengths and, for example, have a total light transmittance of 90% or higher for light having a visible wavelength. The hollow filler contributes to reducing the refractive index of the planarization layer 40. The medium is interposed between hollow filler particles and bonds the hollow filler particles to each other, thereby stabilizing the planarization layer 40.

An example of the material suitable for the hollow filler may include a silicon dioxide (silica, SiO₂). A hollow filler including silica is inexpensive and has high transparency to visible wavelengths, and physical stability. With the hollow filler disposed in a low-refractive-index layer, air regions are dispersed within the planarization layer 40. As a result, the refractive index of the planarization layer 40 decreases. As the content of the hollow filler increases, the refractive index of the planarization layer 40 approaches the value of the refractive index of air.

The diffraction grating section 50 includes a base 51 having a layered structure and a plurality of diffraction gratings 52. The base 51 covers the surface 40a of the planarization layer 40, and the plurality of diffraction gratings 52 protrude from the base 51 upward in the Z-direction. The base 51 and the diffraction gratings 52 both include thermosetting resin and are integrated into a single unit.

The diffraction gratings 52 have transparency to visible wavelengths and, for example, have a total light transmittance of 90% or higher for light having a visible wavelength. The diffraction gratings 52 are periodically provided with a predetermined interval in the X-direction and the Y-direction. Light incident on the diffraction gratings 52 from above toward below in the Z-direction is diffracted by the diffraction gratings 52. The light is diffracted with respect to the normal along the Z-direction at a diffraction angle determined by the wavelength of light and the pitch of the diffraction gratings 52. The light propagates in different directions depending on the wavelength.

The dimension, the pitch, and the like of the diffraction gratings 52 may be set as appropriate in accordance with, for example, the objective.

Conventionally, three-dimensional sensing devices that use a CMOS image sensor have been developed. The diffraction gratings are used to convert a two-dimensional image captured by the CMOS image sensor into a three-dimensional image. Thus, by subjecting light divided by the wavelength through the diffraction gratings to image processing, the distance can be measured based on a range image.

In such a three-dimensional device configuration, the color filters 28 and the microlenses 31 are formed on a semiconductor substrate including CMOS image sensors, following which the planarization layer 40 is formed to planarize the irregularities caused by the surfaces of the microlenses 31 and to increase the optical path, and the diffraction gratings are formed on the upper surface of the planarization layer 40.

FIG. 2(a) to 2(c) are schematic cross-sectional views illustrating a manufacturing process of a solid-state imaging element according to a comparative example. In FIG. 2, the illustration of the configuration below the planarization layer 72 is simplified. FIG. 2 illustrates a semiconductor substrate 70 including CMOS image sensors, microlenses 71, and a planarization layer 72.

As illustrated in FIG. 2(a), a resist coating layer 73 is formed over the entire upper surface of the planarization layer 72 using a transparent photosensitive positive resist. The resist to be used here may be a resist for microlens applications.

After the resist coating layer 73 is formed as illustrated in FIG. 2(a), exposure and development are performed to pattern a plurality of diffraction gratings 74 in FIG. 2(b). The diffraction gratings 74 are subjected to thermal flow (baking) in FIG. 2(c). Consequently, the plurality of diffraction gratings 74 are patterned on the surface of the planarization layer 72.

However, as illustrated in FIG. 2(c), the thermal flow (baking) undesirably deformed the entire surface 74a of each diffraction grating 74 into a convex curved form, which degraded the rectangularity.

When the rectangularity is degraded in this manner, influence on the refraction of light is increased, and light collection efficiency is decreased, thereby degrading the optical characteristics (sensor characteristics).

The term “optical characteristics (sensor characteristics)” refers to the detection accuracy in measuring the distance to an object. When the optical characteristics are degraded, the detection accuracy of the distance is decreased, and it is therefore required to improve the rectangularity of the diffraction gratings.

FIG. 3 is a schematic view of the diffraction gratings illustrating a pattern shape and diffracted light. Each figure in FIG. 3 schematically illustrates the cross-sectional shape of the diffraction grating, and the arrows represent the diffracted light. As illustrated in FIG. 3(a), when the diffraction grating has a rectangular shape, the refraction of light is small. In contrast, when the diffraction grating has a trapezoidal shape as illustrated in FIG. 3(b), an inverted trapezoidal shape as illustrated in FIG. 3(c), or a rectangular shape on one side and an inclination on one side as illustrated in FIG. 3(d), the influence on the refraction of light is increased. Given the circumstances, the present embodiment specifies the inclination angle of the side surface to reduce the influence on the refraction of light.

The solid-state imaging element 10 according to the present embodiment improves the rectangularity of the diffraction gratings 52 compared with the conventional diffraction gratings, making it possible to achieve favorable sensor characteristics. The following section will primarily describe the shape of the diffraction grating section 50 in detail.

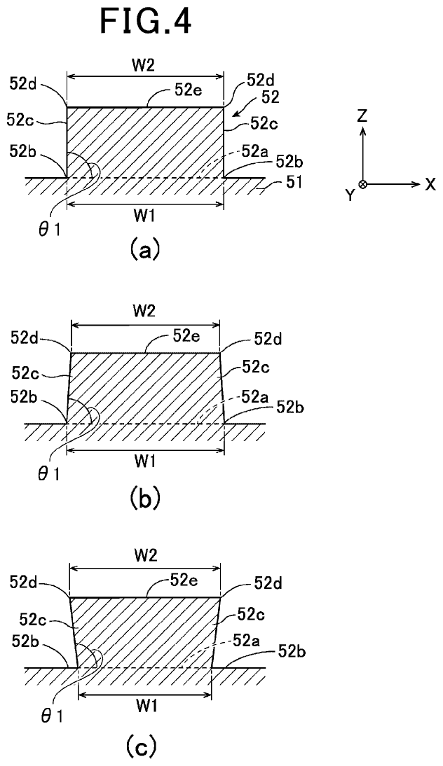

FIG. 4 illustrates an enlarged cross-sectional view of only the diffraction grating 52 illustrated in FIG. 1 in an enlarged manner.

As illustrated in FIG. 4(a), the diffraction grating 52 includes a lower surface 52a, side surfaces 52c, and an upper surface 52e. The lower surface 52a faces toward the planarization layer 40, the side surfaces 52c extend upward in the Z-direction from foot 52b of the lower surface 52a, the upper surface 52e extends from the upper edge of each side surface 52c with an inflection point 52d interposed therebetween, and the upper surface 52e is flat and opposed to the lower surface 52a in the thickness direction (Z-direction).

Note that, the lower surface 52a of the diffraction grating 52 is integrated with a base 51 and is indicated by an imaginary line (a dotted line). The lower surface 52a is the same surface as the surface of the base 51. In FIG. 4(a), the lower surface 52a is illustrated as the same surface as an X-Y plane.

In FIG. 4(a), the side surfaces 52c extend parallel to the Z-direction in the drawing, that is, in a vertical direction, and the upper surface 52e is formed by a surface parallel to the lower surface 52a. Thus, the angle θ1 between the lower surface 52a and each side surface 52c is 90°. As described above, the diffraction grating 52 illustrated in FIG. 4(a) is formed in an ideal rectangular shape.

In the present embodiment, as will be described later, the diffraction gratings 52 are formed by dry etching using a thermosetting resin. This improves the rectangularity of the diffraction gratings 52. Accordingly, the present embodiment requires the diffraction grating section 50 to include the thermosetting resin.

The material of the thermosetting resin may be selected from, for example but not limited to, acrylic resin, epoxy resin, phenol resin, silicone resin, melamine resin, and urea resin.

The diffraction grating 52 illustrated in FIG. 4(a) has a rectangular shape. Thus, a width dimension W1 of the lower surface 52a and a width dimension W2 of the upper surface 52e have the same length.

In contrast, the side surfaces 52c are inclined in FIG. 4(b). Thus, the width dimension W2 of the upper surface 52e is smaller than the width dimension W1 of the lower surface 52a. In FIG. 4(b), the side surfaces 52c on both sides have the same inclination angle. Thus, the cross-sectional shape of the diffraction grating 52 is a trapezoidal shape. As used herein, the term “trapezoidal shape” refers to a shape having an upper base (upper surface) and a lower base (lower surface), which only need to be substantially parallel to each other, and is not to be construed as a concept that includes only geometric trapezoids. For example, the trapezoidal shape includes a shape in which one of the side surfaces extends in the vertical direction and the other one of the side surfaces is inclined as illustrated in FIG. 3(d). Note that however, the side surfaces 52c on both sides having the same inclination angle make the refraction of light to be symmetrical (see FIG. 3) and facilitate the formation of the diffraction grating 52, which is preferable.

In the present embodiment, the lower limit value of the angle θ1 between the lower surface 52a and the side surface 52c of the diffraction grating 52 illustrated in FIG. 4(b) is set to 80°.

In contrast, the diffraction grating 52 illustrated in FIG. 4(c) has an inverted trapezoidal shape in which the side surfaces 52c include reverse-tapered surfaces, and the width dimension W2 of the upper surface 52e is greater than the width dimension W1 of the lower surface 52a.

In the present embodiment, the upper limit value of the angle θ1 between the lower surface 52a and the side surface 52c of the diffraction grating 52 is set to 100°.

As described above, the present embodiment specifies the angle θ1 between the lower surface 52a and the side surface 52c of the diffraction grating 52 to be 80° or more and 100° or less. Note that however, the angle θ1 includes a manufacturing error and a measurement error, and the angle θ1 plus or minus a few degrees is included in the angle θ1 of the present embodiment. Thus, light incident on the side surface 52c is also diffracted similarly to the light incident on the upper surface 52e when the light is refracted and guided into the interior, which improves the usage efficiency of light. Accordingly, by applying to the solid-state imaging element 10 of the present embodiment, various kinds of high-performance sensors are formed. For example, by applying to a range image sensor, the range measurement accuracy and the like are improved.

A method of measuring the angle θ1 will be described. For example, a cross-sectional profile is acquired using an atomic force microscope or the like, and the foot 52b and the inflection points 52d are determined on the cross-sectional profile. The lower surface 52a is determined by drawing a straight line between the foot 52b on both sides. Furthermore, a straight line is drawn between each foot 52b and the corresponding inflection point 52d to determine the side surface 52c. Thereafter, the angle θ1 between the lower surface 52a and the side surface 52c is measured.

When the foot 52b and the inflection points 52d are rounded, the lower surface 52a and the upper surface 52e may be determined excluding an arc that contacts the rounded part, and a straight line may be drawn between the edges of the lower surface and the upper surface to thereby specify the side surfaces 52c.

For the lower surface 52a, the surface of the base 51 positioned on both sides of the diffraction grating 52 or the surface of the planarization layer 40 may be regarded as the lower surface 52a of the diffraction grating 52 for measuring the angle θ1.

Further, in the present embodiment, the width dimension W1 of the lower surface 52a and the width dimension W2 of the upper surface 52e are, although not being limited thereto, approximately 0.50 μm or more and 1.70 μm or less. Additionally, the distance between the upper surface 52e and the lower surface 52a (the thickness dimension of the diffraction grating 52) is approximately 0.30 μm or more and 0.80 μm or less.

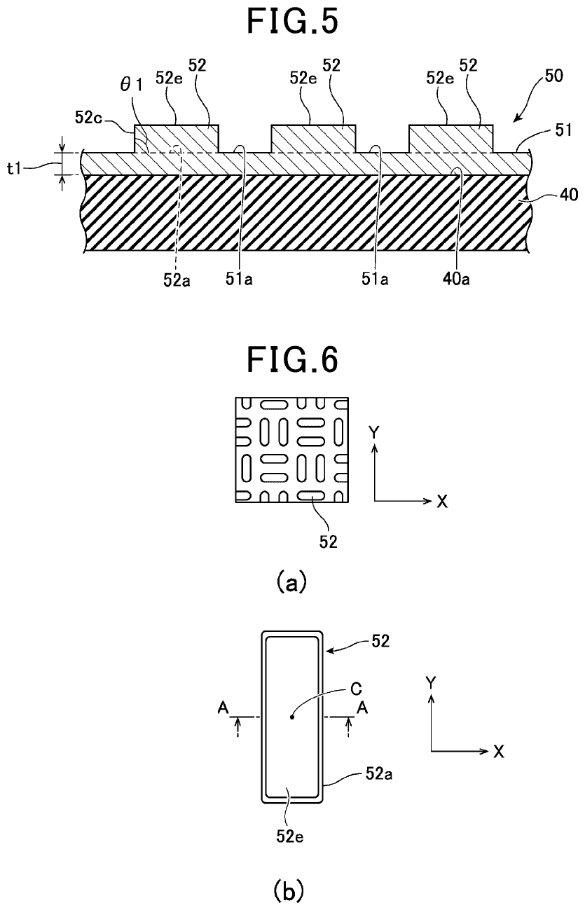

The solid-state imaging element 10 according to another embodiment has a stacked structure illustrated in FIG. 1. As illustrated in FIG. 5 in an enlarged manner, the diffraction grating section 50 includes the base 51, which covers the entire surface 40a of the planarization layer 40, and the plurality of diffraction gratings 52, which protrude from the base 51.

In the present embodiment, the diffraction grating layer formed on the entire surface 40a of the planarization layer 40 is etched up to a certain depth by dry etching, thereby forming a residual film layer between the diffraction gratings 52. The residual film layer is integrated with the lower surface 52a of each diffraction grating 52 and constitutes the base 51 having a layered structure. Providing the base 51 protects the planarization layer 40 and appropriately guides the diffracted light, which leads to an improvement in the sensor characteristics.

Although not limited, it is preferable that the thickness dimension t1 of the base 51 be approximately 0.3 μm or more and 1.0 μm or less. The surface 40a of the planarization layer 40 is appropriately protected by ensuring the thickness dimension t1 of the base 51. That is, the planarization layer 40 contains, for example, a filler as described above. Thus, the surface 40a of the planarization layer 40 is not a true plane but is roughened. Given the circumstances, the base 51 having the thickness dimension t1 as described above reliably covers the entire surface 40a of the planarization layer 40. Note that the term “planarization” of the planarization layer 40 means to smooth out the irregularities caused by the surfaces of the microlenses 31 to make the shape flatter than the surfaces of the microlenses 31 and is not limited to only a true plane.

The embodiment described in FIG. 5 is characterized in that the surface roughness Ra of a surface 51a of the base 51 between the diffraction gratings 52 is 100 Å or less. The surface roughness Ra is an arithmetic mean roughness. The arithmetic mean roughness was measured using an atomic force microscope (AFM) (Equipment name: NX20 300 mm from Park Systems). The Ra value was verified using AFM data analysis software.

Although the surface 51a of the base 51 is influenced by dry etching, the surface roughness Ra of the surface 51a of the base 51 is reduced to a value of 100 Å or less by, for example, adjusting the etching time. In the present embodiment, the surface roughness Ra is set to preferably 99.5 Å or less, more preferably 99 Å or less, even more preferably 95 Å or less, and yet more preferably 90 Å or less.

The surface 51a of the base 51 of the diffraction grating section 50 is a region that scatters light and does not allow light to be transmitted therethrough. However, when the surface roughness Ra is increased, the surface 51a also functions as a diffraction grating, allowing some of light to be transmitted therethrough and facilitating spreading of interference fringes. In the present embodiment, the surface roughness Ra of the surface 51a of the base 51 is reduced to 100 Å or less, thereby inhibiting the spreading of the interference fringes, and thus achieving favorable sensor characteristics.

In FIG. 5, the side surfaces 52c of the diffraction gratings 52 are illustrated as vertical surfaces. However, as illustrated in FIG. 4(b) and 4(c), the side surfaces 52 may be a forward-tapered surface or a reverse-tapered surface. In this case, the angle θ1 between the lower surface 52a and the side surface 52c of the diffraction grating 52 is preferably 80° or more and 100° or less.

FIG. 6 is a schematic plan view of the diffraction gratings 52 according to the present embodiment illustrating the planar shape of the diffraction gratings 52. As illustrated in FIG. 6(a), the plurality of diffraction gratings 52 have an elongated shape and are regularly arranged with intervals. However, the arrangement illustrated in FIG. 6(a) is merely an example and not intended to be limiting. That is, although the embodiment illustrated in FIG. 6(a) includes the diffraction gratings 52 elongated in the Y-direction and the diffraction gratings 52 elongated in the X-direction, the plurality of diffraction gratings 52 may include only the diffraction gratings 52 elongated in the Y-direction or only the diffraction gratings 52 elongated in the X-direction. Alternatively, the plurality of diffraction gratings 52 may include diffraction gratings 52 inclined with respect to the X-direction and the Y-direction. The aspect ratio of the diffraction gratings 52 elongated in the X-direction and the diffraction gratings 52 elongated in the Y-direction is not limited and may be set as appropriate in accordance with the desired sensor characteristics or use.

FIG. 6(b) is an enlarged plan view of the diffraction grating 52 illustrated in FIG. 6(a). The cross-sectional view taken along line A-A passing through the center C of the diffraction grating 52 illustrated in FIG. 6(b) as viewed from the arrow direction corresponds to each of the cross-sections in FIG. 4. In FIG. 6(b), the diffraction grating 52 is cut along a transverse direction (the X-direction). However, the diffraction grating 52 may be cut along a longitudinal direction (Y-direction) to pass through the center C, or may be cut diagonally with respect to the X-direction and the Y-direction to pass through the center C. In these cases also, the shape that appears on the cross-section is preferably a rectangular shape, a trapezoidal shape, or an inverted trapezoidal shape as illustrated in FIG. 4.

Note that the numerical values of the width dimensions W1 and W2 described above are dimensions of the cross-section that appears when the diffraction grating 52 is cut along the transverse direction. The width dimensions (W1 and W2) of the cross-section that appears when the diffraction grating 52 is cut along the longitudinal direction are approximately 0.3 μm or more and less than or equal to a pixel area size.

As described in the comparative example of FIG. 2, it was found that the diffraction grating formed by permanently fixing a photosensitive resist through baking did not achieve the designed performance. That is, in the comparative example, the resists were protrusions and were undesirably deformed to be rounded, which significantly affected the refraction of light and led to the degradation of the sensor characteristics.

Given the circumstances, the inventors solved the above issue by not using the photosensitive resist itself as the diffraction gratings and by adjusting the inclination angle so as not to form an extremely forward-tapered surface or an extremely reverse-tapered surface.

Additionally, if the surface roughness Ra of the residual layer between the diffraction gratings is increased as a result of forming the diffraction gratings by a dry etching process, the sensor characteristics are also degraded. Accordingly, the manufacturing method that reduces the surface roughness Ra of the residual layer between the diffraction gratings to be less than or equal to a predetermined value and achieves favorable sensor characteristics has been devised.

An example of the method of manufacturing the solid-state imaging element 10 of the present embodiment will be described with reference to the drawings.

First, the color filters 28 are provided on the substrate 20 in which the CMOS image sensors 24 are formed. Additionally, the plurality of microlenses 31 arranged in a two-dimensional array are formed. The method of forming the microlenses 31 includes, for example, applying a layer of high-refractive-index material, which becomes the microlenses 31, on at least the surfaces 28a of the color filters 28, providing a photoresist layer on the high-refractive-index material, and etching the underlying high-refractive-index material layer using a lens pattern formed by thermal reflow after the photolithography process.

Next, a coating liquid in which a low-refractive-index material containing a hollow filler and a medium is dispersed is applied to cover the surfaces of the color filters 28 and the microlenses 31, and to cover the surface 20a of the substrate 20 exposed between the color filters 28 and the microlenses 31. The applied coating liquid is heated and cured to remove solvent. Thus, the planarization layer 40 is formed.

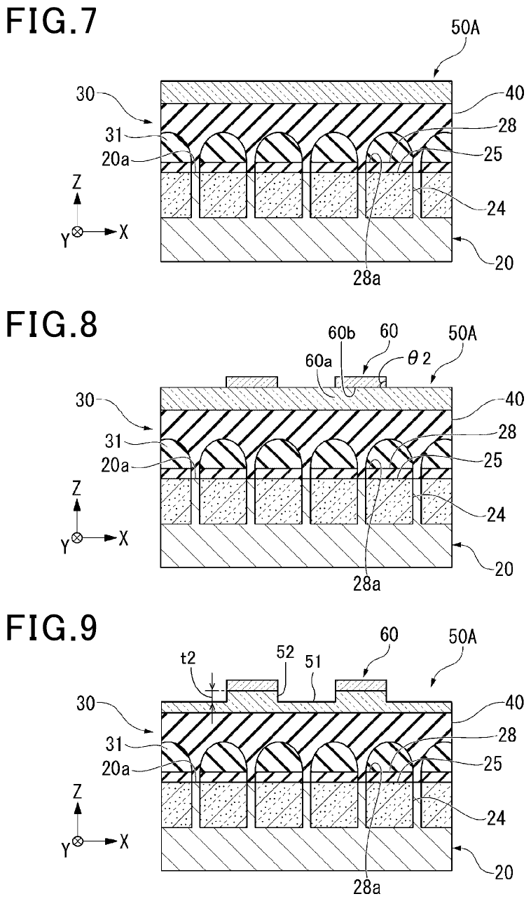

Next, as illustrated in FIG. 7, the thermosetting resin layer 50A is formed on the planarization layer 40 (step A). The thickness of the thermosetting resin layer 50A is greater than or equal to the sum of the thickness of the base 51 and the thickness of the diffraction grating 52 (the thickness dimensions t1+t2 illustrated in FIG. 1).

Furthermore, a sacrificial pattern 60 corresponding to the diffraction grating 52 is formed on the thermosetting resin layer 50A as illustrated in FIG. 8 using a transparent photosensitive resist (step B). The sacrificial pattern 60 is formed, for example, in a planar pattern as illustrated in FIG. 6(a).

The sacrificial pattern 60 is formed by applying a layer of resist and subjecting the resist to exposure and development processes using a photomask. However, the sacrificial pattern 60 is not cured by baking because it is not used as a permanent film and also to keep the cross-section of the sacrificial pattern 60 in a rectangular shape.

As illustrated in FIG. 8, a side surface 60a of the sacrificial pattern 60 is preferably formed in a vertical direction along the Z-direction. However, it is sufficient that the side surface 60a has an inclination angle θ2 in the range of 80° to 100°.

In the present embodiment, the depth of field (focus) during exposure is adjusted as appropriate in forming the sacrificial pattern 60 using the photoresist. Accordingly, the inclination angle θ2 of the side surface 60a of the sacrificial pattern 60 is adjusted to be 80° or more and 100°or less. The inclination angle θ2 is defined by the angle between the lower surface 60b and the side surface 60a of the sacrificial pattern 60.

Furthermore, the angle θ1 (see FIG. 4) of the transferred diffraction grating is adjusted by adjusting, as appropriate, the gas type used in transferring the pattern by a dry etching method, the pressure, the time period, etc. For example, although not limited thereto, an epoxy resin may be used as the thermosetting resin, the thickness of the thermosetting resin 50A (the thickness dimensions t1+t2 illustrated in FIG. 1) may be set to approximately 1.4±0.1 μm, the gas type may be CF₄ or CHF₃, the chamber pressure during dry etching may be set to approximately 6 Pa to 10 Pa, and the time period of dry etching may be set to 2.5 minutes to 3.5 minutes.

Subsequently, as illustrated in FIG. 9, dry etching using the sacrificial pattern 60 is performed (step C). As a result, the shape of the sacrificial pattern 60 is transferred to the thermosetting resin layer 50A, thereby forming the diffraction gratings 52. Dry etching is completed without removing all of the thermosetting resin layer 50A at parts where the sacrificial pattern 60 is not present, and leaving some of the thermosetting resin layer 50A. At this time, the depth dimension t2 is adjusted using the dry etching conditions. The depth dimension t2 is a thickness dimension of the diffraction grating 52. Consequently, as illustrated in FIG. 9, the thermosetting resin layer 50A becomes the diffraction grating section 50 in which the plurality of diffraction gratings 52 protrude on the base 51, which covers the planarization layer 40 without gaps. Thereafter, the sacrificial pattern 60 illustrated in FIG. 9 is removed.

In the present embodiment, by forming the diffraction grating based on the above-described dry etching condition, the angle θ1 of the side surface 52c of the diffraction grating 52 is accurately adjusted to be within the range of 80° or more and 100° or less. Additionally, the surface roughness Ra of the surface 51a of the base 51 remaining between the diffraction gratings 52 is adjusted to be 100 Å or less.

The diffraction gratings according to the present embodiment diffract the incident light as designed. Therefore, by applying the diffraction gratings according to the present embodiment to the solid-state imaging element 10, various high-performance sensors are formed. For example, applying the solid-state imaging element according to the present embodiment to a range image sensor improves the range measurement accuracy and the like.

When the refractive index is low, the planarization layer 40 has a porous structure with many gaps as described above. In the structure according to the present embodiment, the base 51 completely covers the planarization layer 40, and thus the present embodiment is advantageous in the planarization layer 40 is suitably protected, and the detachment of fillers and penetration of liquids are prevented.

Although certain embodiments of the present disclosure have been described in detail, the present disclosure is not limited to a particular embodiment. The present disclosure should encompass modifications, combinations, or the like of the configurations, in the range not departing from the spirit of the present disclosure. Although some modifications will be illustrated below, these are not intended to represent all of the modifications, and other modifications are also possible. Two or more of these modifications may be combined as appropriate.

Although the above-described embodiment illustrates an on-chip type solid-state imaging element in which color filters are directly formed on the substrate, the scope of application of the technical ideas according to the present disclosure is not limited to this embodiment, and the technical ideas are applicable to diffraction gratings and the like to be provided on, for example, an organic EL (OLED).

The present disclosure will be described in detail below using examples executed to clarify advantageous effects of the present disclosure. Note that the present disclosure is not limited to the following examples in any way.

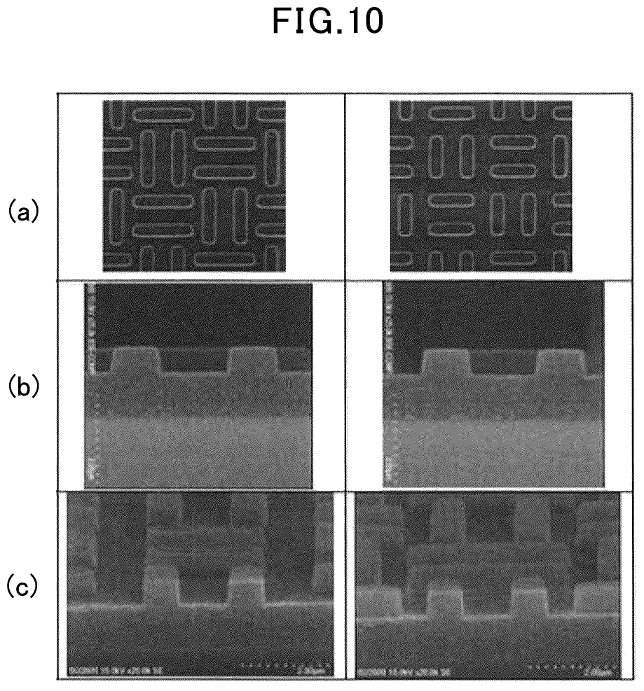

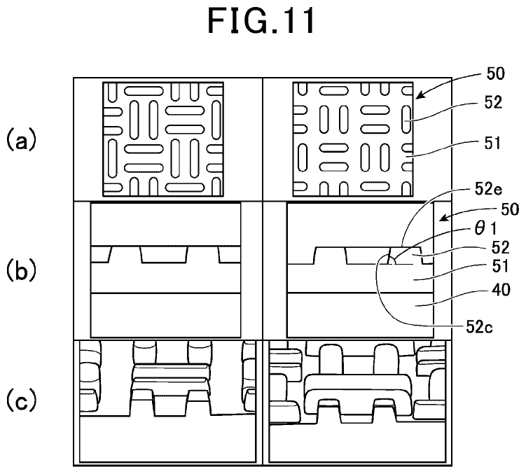

FIG. 10 illustrates scanning electron microscope (SEM) images of the diffraction grating section 50 according to the present embodiment fabricated by the manufacturing method described above. FIG. 11 describes schematic renderings of these images. FIG. 10(a) is an SEM micrograph in plan view. FIG. 11(a) is a schematic diagram of FIG. 10(a). FIG. 10(b) is an SEM micrograph of the cross-section. FIG. 11(b) is a schematic diagram of FIG. 10(b). FIG. 10(c) is an SEM micrograph as viewed from obliquely above. FIG. 11(c) is a schematic diagram of FIG. 10(c). As illustrated in FIG. 10(a), 10(c), 11(a), and 11(c), it was observed that the plurality of diffraction gratings 52 were regularly arranged.

As illustrated in FIG. 10(b) and 11(b), it was observed that the diffraction gratings 52 were substantially rectangular or substantially trapezoidal, and the plurality of diffraction gratings 52 protruded on the base having a layered structure.

Furthermore, it was observed that the upper surface 52e of the diffraction grating 52 was substantially flat and substantially parallel to the upper surface of the base 51 and the planarization layer 40. Additionally, it was observed that the side surface 52c in the cross-section was a steeply inclined surface.

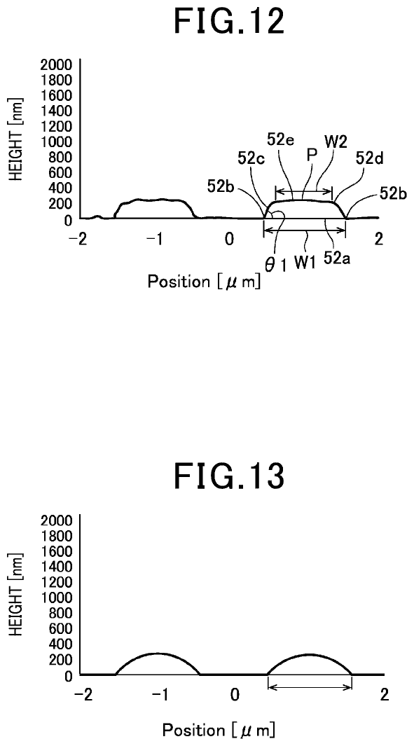

FIG. 12 is a cross-sectional profile of the diffraction gratings fabricated by the manufacturing method of the present example. FIG. 13 is a cross-sectional profile of the diffraction gratings fabricated by the manufacturing method of the comparative example illustrated in FIG. 2.

The cross-sectional profiles illustrated in FIGS. 12 and 13 were measured using an atomic force microscope (AFM). The diffraction gratings of the example illustrated in FIG. 12 were substantially trapezoidal, but the entire surfaces of the diffraction gratings of the comparative example illustrated in FIG. 13 were oval.

The width dimension W1 of the lower surface 52a of the diffraction grating of the example illustrated in FIG. 12 was about 1.1 μm. The width dimension W2 of the upper surface 52e was about 0.9 μm. Additionally, the angle θ1 of the side surface 52c of the diffraction grating 52 was about 80°. In this manner, the inclination angle of the side surface 52 was obtained using the cross-sectional profile. Note that the measurement error is allowed in a certain range (for example, ±a few percent).

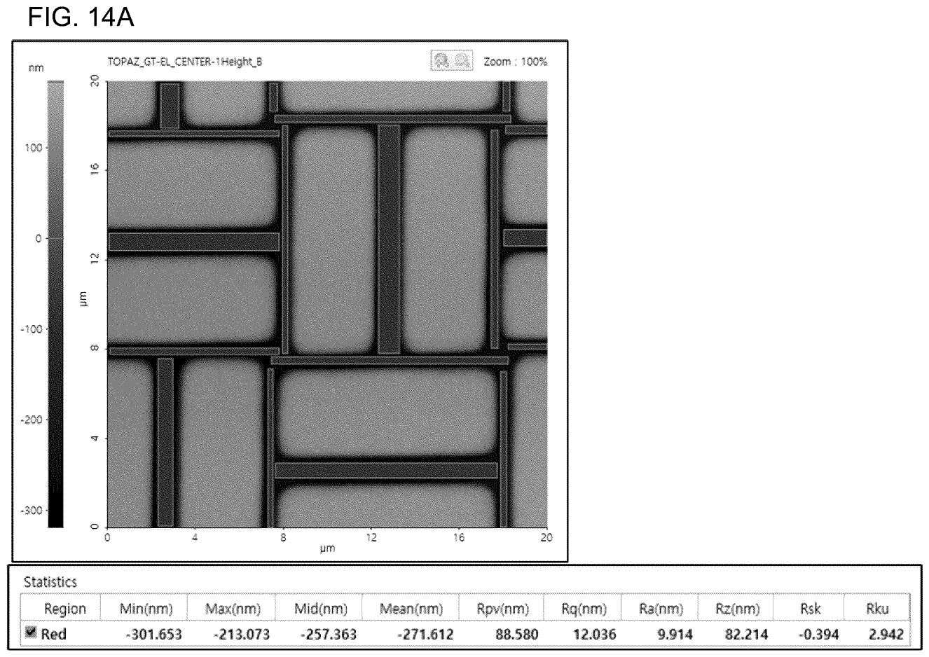

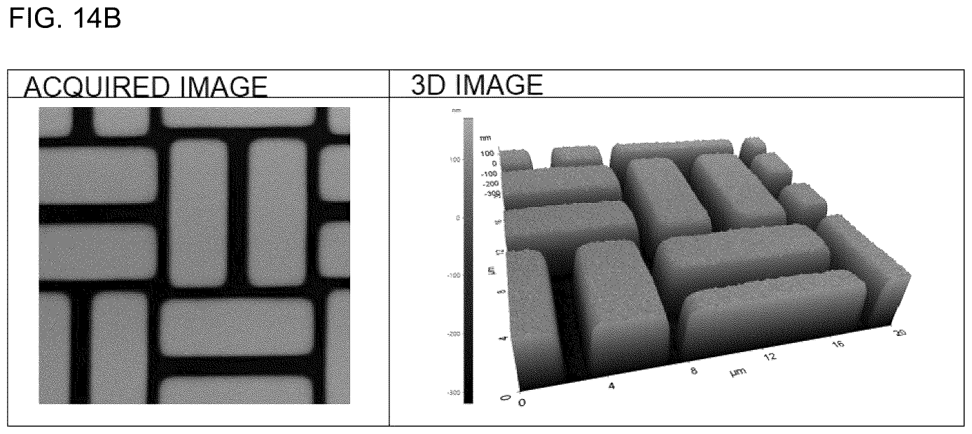

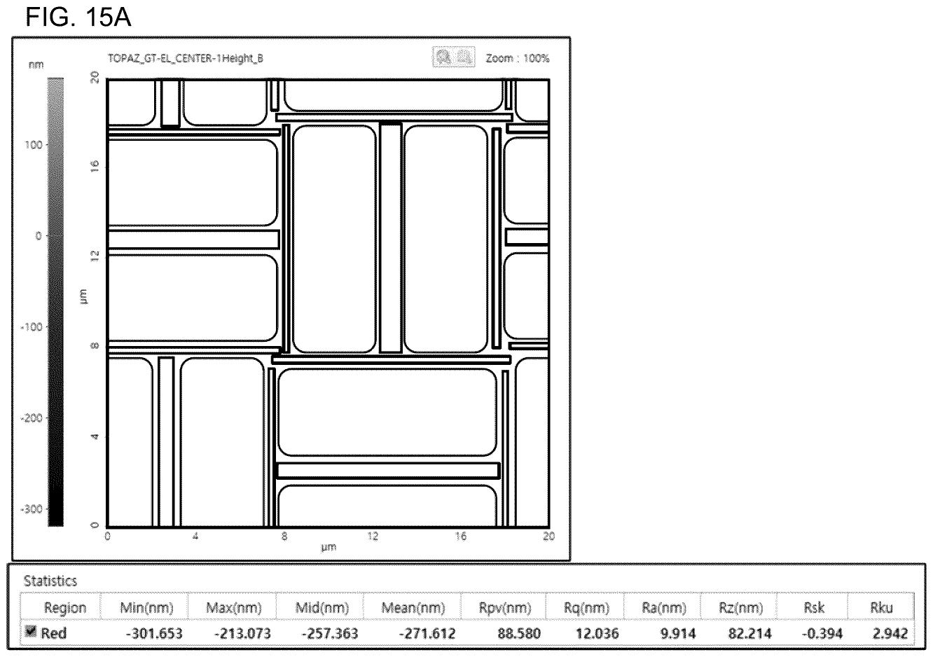

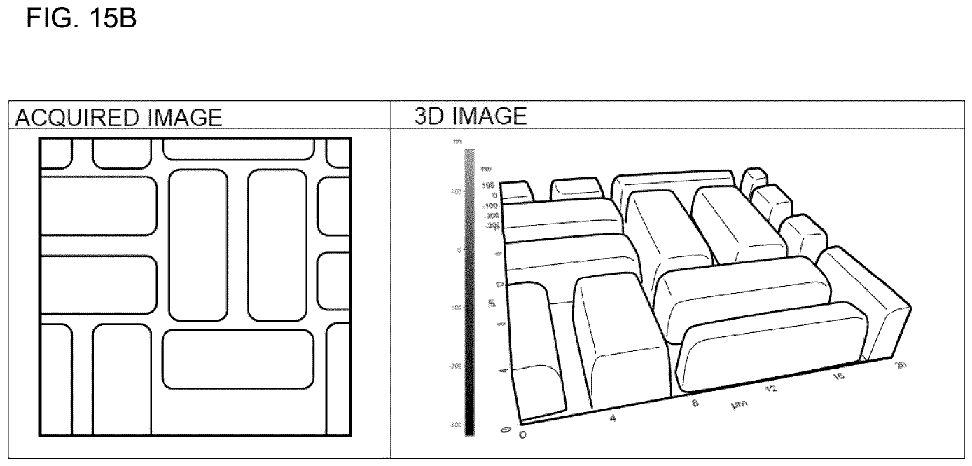

FIGS. 14A and 14B are image data used in the experiment regarding the surface roughness Ra of the surface between the diffraction gratings. FIGS. 15A and 15B describe schematic renderings of FIGS. 14A and 14B, respectively. The image data enables acquisition of a three-dimensional image or the like based on an acquired image (SEM micrograph) illustrated in FIG. 14B.

Parts surrounded by frames in FIGS. 14A and 15A are the base remaining between the diffraction gratings. The surface roughness Ra of the base was measured using the atomic force microscope (AFM) (Equipment named NX20 300 mm available from Park Systems). The Ra value was verified using AFM data analysis software. The surface roughness Ra was obtained based on the average roughness of all the parts surrounded by the frames in FIGS. 14A and 15A and was 99.14 Å.

The dry etching time required to obtain the diffraction gratings illustrated in FIGS. 14A and 14B was 2 minutes and 45 seconds. The longer the dry etching time, the greater the surface roughness Ra becomes, which deteriorates the optical characteristics. The dry etching time was therefore set to 2.5 minutes to 3.5 minutes based on the present example. As a result, it was found that the surface roughness Ra of the surface between the diffraction gratings can be set to be 100 Å or less and preferably 99.5 Å or less.

Embodiments of the present disclosure may achieve a solid-state imaging element excellent in the sensor characteristics and may be favorably applied to a three-dimensional sensing device.

Embodiments of the present disclosure may provide a solid-state imaging element in which a diffraction grating pattern is formed with high shape accuracy on a lens array and a method of manufacturing the solid-state imaging element.

Obviously, numerous modifications and variations of the present invention are possible in light of the above teachings. It is therefore to be understood that within the scope of the appended claims, the invention may be practiced otherwise than as specifically described herein.

1. A solid-state imaging element comprising:
a lens array including a plurality of microlenses arranged in a regular manner;
a planarization layer formed on the lens array; and
a diffraction grating section including a thermosetting resin, the diffraction grating section including a plurality of diffraction gratings and being provided on the planarization layer, wherein
an angle between a lower surface and a side surface of each diffraction grating is 80° or more and 100° or less.

2. The solid-state imaging element according to claim 1, wherein the side surfaces on both sides of the diffraction grating are formed at a substantially same angle relative to the lower surface of the diffraction grating.

3. The solid-state imaging element according to claim 1, wherein the diffraction grating section includes a base covering an upper surface of the planarization layer, and the diffraction gratings protrude from the base.

4. The solid-state imaging element according to claim 3, wherein the base between the diffraction gratings has a surface roughness Ra of 100 Å or less.

5. The solid-state imaging element according to claim 4, wherein the surface roughness Ra is 99.5 Å or less.

6. The solid-state imaging element according to claim 1, wherein the planarization layer has a refractive index lower than a refractive index of the microlenses.

7. A solid-state imaging element comprising:
a lens array including a plurality of microlenses arranged in a regular manner;
a planarization layer formed on the lens array; and
a diffraction grating section including a thermosetting resin, the diffraction grating section including a base covering an upper surface of the planarization layer and a plurality of diffraction gratings protruding from the base, wherein
the base between the diffraction gratings has a surface roughness Ra of 100 Å or less.

8. The solid-state imaging element according to claim 7, wherein the surface roughness Ra is 99.5 Å or less.

9. The solid-state imaging element according to claim 7, wherein the planarization layer has a refractive index lower than a refractive index of the microlenses.

10. A method of manufacturing a solid-state imaging element, comprising:
(A) forming a planarization layer on a lens array including a plurality of microlenses arranged in a regular manner and forming a thermosetting resin layer on the planarization layer;
(B) forming a sacrificial pattern on the thermosetting resin layer, the sacrificial pattern corresponding to a diffraction grating;
(C) forming a plurality of diffraction gratings by performing dry etching and transferring a shape of the sacrificial pattern on the thermosetting resin layer, wherein
said forming (C) includes adjusting an angle between a lower surface and a side surface of each diffraction grating to be 80° or more and 110° or less.

11. The method according to claim 10, wherein the side surfaces on both sides of the diffraction grating are formed at a substantially same angle relative to the lower surface of the diffraction grating.

12. The method according to claim 10, further comprising:
forming a base covering an upper surface of the planarization layer, wherein the diffraction gratings protrude from the base.

13. The solid-state imaging element according to claim 12, wherein the base between the diffraction gratings has a surface roughness Ra of 100 Å or less.

14. The solid-state imaging element according to claim 13, wherein the surface roughness Ra is 99.5 Å or less.

15. The method according to claim 12, wherein the base is formed by leaving part of the thermosetting resin layer between the diffraction gratings.

16. The solid-state imaging element according to claim 10, wherein the planarization layer has a refractive index lower than a refractive index of the microlenses.

17. A method of manufacturing the solid-state imaging element, comprising:
(A) forming a planarization layer on a lens array including a plurality of microlenses arranged in a regular manner and forming a thermosetting resin layer on the planarization layer;
(B) forming a sacrificial pattern on the thermosetting resin layer, the sacrificial pattern corresponding to a diffraction grating; and
(C) forming a plurality of diffraction gratings by performing dry etching and transferring a shape of the sacrificial pattern on the thermosetting resin layer, wherein
said forming (C) includes leaving part of the thermosetting resin layer between the diffraction gratings, the part of the thermosetting resin layer having a surface roughness Ra of 100 Å or less.

18. The method according to claim 17, wherein the surface roughness Ra is 99.5 Å or less.

19. The method according to claim 17, wherein the planarization layer has a refractive index lower than a refractive index of the microlenses.
